(19) United States
(12) Patent Application Publication
(10) Pub. No.: US 2006/0203309 A1
(43) Pub. Date: Sep. 14, 2006

(54) Image forming apparatus and image forming method

(75) Inventor: Masatsugu Hirayama, Yokohama-shi (JP)

Correspondence Address: FOLEY AND LARDNER LLP;SUITE 500, 3000 K STREET NW, WASHINGTON, DC, 20007, US

(73) Assignees: KABUSHIKI KAISHA TOSHIBA; TOSHIBA TEC KABUSHIKI KAISHA

(21) Appl. No.: 11/076,327

(22) Filed: Mar. 10, 2005

(51) Int. Cl. G03F 3/08; G06F 15/00

(52) U.S. Cl. 358/504; 358/518; 358/1.9; 358/519

(57) ABSTRACT

An image forming apparatus comprising a recording unit which records a plurality of calibration data, an image forming unit which reads said plurality of calibration data and forms images of a plurality of calibration patterns on a recording medium according to said plurality of calibration data, a reading unit which reads the images of said plurality of calibration patterns to output image data, a computing unit which receives said plurality of image data, and computes a plurality of image correction amounts by comparing the plurality of image data to a plurality of reference image data previously prepared, and an image processing unit which performs image correction to document image data newly read by the reading unit according to said plurality of image correction amounts.

### BACKGROUND OF THE INVENTION

Recently, as performance of an image forming apparatus such as a digital copying machine is improved, integrated digital equipment having not only a copying function but also a function as a printer is developed and becomes widespread. Usually, in PPC and multi-function peripherals (MFP), because density and gradation characteristics of an output image fluctuate by an environmental change (temperature and humidity), a calibration pattern according to a built-in pattern is outputted, the calibration pattern is read by placing the outputted calibration pattern image on a document glass, and the calibration is performed to correct the output image. Therefore, even if the environment is changed, the stable density and gradation characteristics can be obtained.

Jpn. Pat. Appln. KOKAI Publication No. 2001-180090 discloses a calibration pattern accompanied by an identification code for identifying which calibration pattern is printed to correspond to which printer when a PC or the like outputs plural calibration patterns to plural printers. The identification code is used when the one calibration pattern corresponds to one printer.

However, for example, in the MFP, the calibration for a printer is required in addition to the calibration for a copying machine, and there is a problem that the image correction cannot always be performed by the common calibration in the printer and the copying machine.

### BRIEF SUMMARY OF THE INVENTION

An embodiment of the present invention is an image forming apparatus comprising: a recording unit which records a plurality of calibration data; an image forming unit which reads the plurality of calibration data from the recording unit, and forms images of a plurality of calibration patterns on a recording medium according to the plurality of calibration data; a reading unit which reads the formed images of the plurality of calibration patterns to output image data; a computing unit which receives a plurality of image data according to the plurality of calibration patterns read by the reading unit, and computes a plurality of image correction amounts by comparing the plurality of image data to a plurality of reference image data previously prepared; an image processing unit which performs image correction to document image data newly read by the reading unit, according to the plurality of image correction amounts computed by the computing unit; and a control unit which controls each unit so as to cause the image forming unit to form the plurality of calibration patterns in a calibration operation mode; to cause the reading unit to read the plurality of calibration patterns; to cause the computing unit to compute the plurality of image correction amounts based on the image data of the read calibration pattern to store the plurality of image correction amounts in a storage area; to cause the image processing unit to perform a correction process of the document image data newly read by the reading unit in a normal image forming operation mode based on the image correction amount; and to cause the image forming unit to form an image on the recording medium according to the image data to which the correction process has been performed.

### BRIEF DESCRIPTION OF THE SEVERAL VIEWS OF THE DRAWING

FIG. 1 is a block diagram showing a configuration of an image forming apparatus according to an embodiment of the present invention;

FIG. 2 is a graph explaining a correction data computing process during a calibration operation of the image forming apparatus;

FIG. 3 is a flowchart showing a calibration operation of the image forming apparatus;

FIG. 4 is an explanatory view showing a selection screen of a calibration pattern output of the image forming apparatus;

FIG. 5 is a flowchart showing a calibration operation of the image forming apparatus;

FIG. 6 is an explanatory view showing a selection screen of the calibration pattern output of the image forming apparatus;

FIGS. 7A and 7B are explanatory views each showing a calibration start direction screen of the image forming apparatus;

FIG. 8 is a flowchart showing a calibration operation using a pattern determining unit in the image forming apparatus;

FIG. 9 is a flowchart showing another calibration operation using the pattern determining unit in the image forming apparatus;

FIG. 10 shows a calibration pattern of the image forming apparatus;

FIGS. 11A and 11B each show a calibration pattern to which mode information of the image forming apparatus is added;

FIGS. 12A and 12B each show a calibration pattern to which the mode information of the image forming apparatus is added; and

FIGS. 13A and 13B each show a calibration pattern to which the mode information of the image forming apparatus is added.

### DETAILED DESCRIPTION OF THE INVENTION

Referring now to the accompanying drawings, an image forming apparatus and an image forming method according to embodiments of the invention will be described in detail.

In the following embodiments of the invention, a multi-function peripheral (MFP) is illustrated as an example of the image forming apparatus according to one embodiment of the invention. In the MFP, different calibrations are required for a copy mode and a printer mode. Further, different calibrations are also required for different page description languages such as PS and PCL. Therefore, it is necessary that the calibration is performed by using plural calibration patterns.

As described below in detail, calibration processes in the plural modes are efficiently performed by utilization of an auto document feeder (ADF), a layout of the calibration pattern, identification information added to the calibration pattern, and the like.

<Image Forming Apparatus of the Embodiment of the Invention>

(Configuration)

FIG. 1 shows a configuration of the image forming apparatus according to an embodiment of the invention. In FIG. 1, an image forming apparatus 1 includes an interface (I/F) unit 8, a print data image processing unit (RIP: Raster Image Processor) 9, an auto document feeder (ADF) unit 10, a scanner unit 11, a color conversion unit 12, a filter unit 13, an black generating unit 14, a gamma correction unit 15, a halftoning processing unit 16, a calibration pattern generating unit 22, a correction data computing unit 18, a CPU 19, a ROM 20, and a RAM 21. The I/F unit 8 receives image information and the like from a PC 2. The print data image processing unit 9 performs an image conversion process of converting the image information so that printing can be performed. The ADF unit 10 automatically conveys a document. The scanner unit 11 scans a document image. The color conversion processing unit 12 converts RGB image signals outputted from the scanner 11 into CMY image signals. The filter unit 13 performs a filtering process. The black generating unit 14 generates black signals from the CMY image signals to output CMYK signals. The gamma correction unit 15 performs gamma correction of the CMYK signals based on correction data stored in the RAM 11. The halftoning processing unit 16 performs a gradation process. The calibration pattern generating unit 22 generates and supplies a calibration pattern under control of the CPU 19. The correction data computing unit 18 is connected to the scanner unit 11. The CPU 19 controls the whole of the image forming apparatus. The ROM 20 and the RAM 21 are connected to the CPU 19. The CPU controls each unit included in the image forming apparatus. An output of the calibration pattern generating unit 22 is supplied to an input of the halftoning processing unit 16. Further, the image forming apparatus 1 according to the embodiment of the invention includes a print unit 17, a pattern determining unit 23, a hard disk driver (HDD) 25, and an operation and display unit 31. The print unit 17 receives print data to perform an image. The pattern determining unit 23 determines the pattern on the image based on the image information supplied from the scanner unit 11. The HDD 25 is controlled by the CPU 19, and is connected to the print data image processing unit 9 and the like. The operation and display unit 31 is connected to the CPU 19, and has various operation switches and an operation display screen.

(Basic Operation)

The image forming apparatus 1 having the above configuration has at least encoding functions such as a printer function and a copier function as the MFP. With reference to the printer function, when the I/F unit 8 receives the image information and the like from the external PC 2 or the like, the print data image processing unit 9 performs the image processing under the control of the CPU 19 so that the image information is formed in a signal format which can be printed by the print unit 17, and the image is formed on a recording medium. At this point, in the print data image processing unit 9, the image processing is performed to the supplied image signals according to the calibration result.

With reference to the copier function in the image forming apparatus 1, when a user places plural documents on the ADF unit 10 to press a start button or the like through the operation and display unit 31, under the control of the CPU 19, the ADF unit 10 sequentially conveys the documents to a document glass (not shown) and the image information is read by the scanner unit 11. Then, the color conversion unit 12 converts the image information such as the RGB image signals into the CMY signals which are of the recording color, the filter unit 13 performs the filtering process, and the black generating unit 14 generates the black signal from the CMY image signals to output the CMYK signals. Further, the gamma correction unit 15 performs the gamma correction affected by the calibration result, and the gradation unit 16 performs the gradation process to supply the CMYK signals to the print unit 17, and the image is formed on the recording medium.

The calibration process performed by the image forming apparatus 1 with respect to plural modes will be described in detail referring to the drawings.

<Calibration Process>

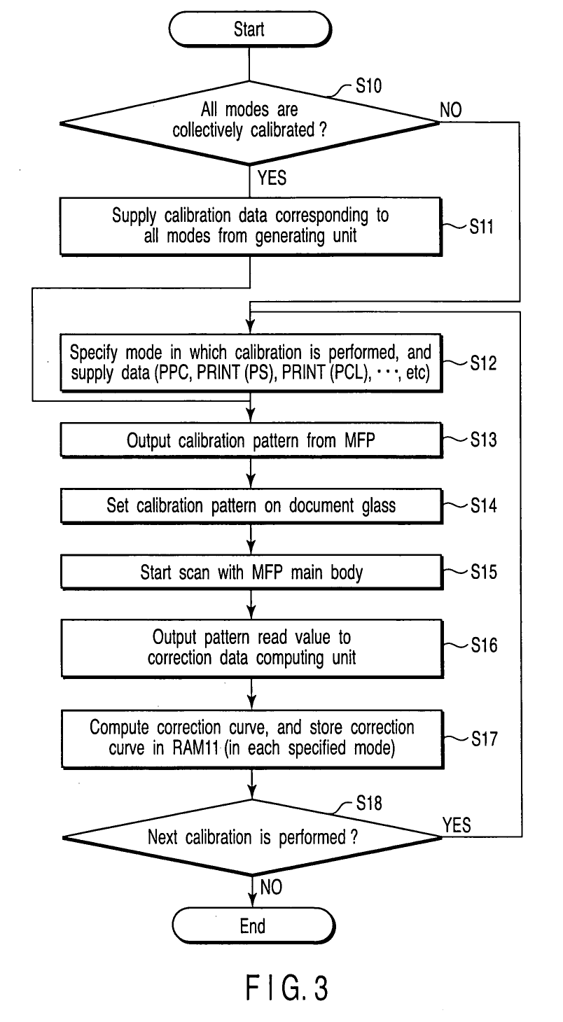

### FIRST EMBODIMENT: FIG. 3

A first embodiment of the invention specifies a image forming apparatus which performs a calibration process with respect to plural modes. FIG. 3 is a flowchart showing an example of a calibration operation of the image forming apparatus according to the first embodiment.

A series of calibration executing operation for a copy operation and a printer operation is divided into a correction pattern output operation and a correction pattern read and correction data computing operation.

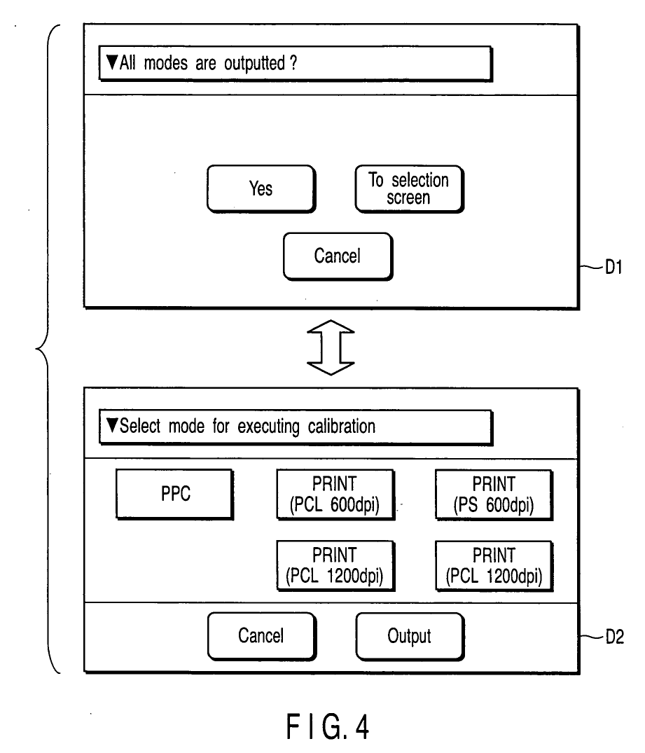

In the image forming apparatus 1, when the calibration operation is specified in the operation and display unit 31 by the selection of the user, the CPU controls the operation and display unit 31 to display mode specifying screens D1 and D2 which performs the calibration as shown in FIG. 4 in order to perform the correction pattern output operation. Namely, first, it is determined whether the calibration patterns for all the modes are displayed or not (S10). When the user directs that all the modes are outputted, the calibration pattern generating unit 22 supplies calibration data for all the modes (for example, PPC, PRINT (PS 600 dpi), PRINT (PS 1200 dpi), PRINT (PCL 600 dpi), and PRINT (PCL 1200 dpi)) to the halftoning processing unit 16 (or the HDD 25 supplies the calibration data to the print unit 17) (S11).

On the other hand, when the user presses “to selection screen” in an operation screen D1 of FIG. 4, an operation screen D2 is displayed. When the user specifies the particular (plural) calibration modes such as PPC, PRINT (PS 600 dpi), PRINT (PS 1200 dpi), PRINT (PCL 600 dpi), PRINT (PCL 1200 dpi), similarly the calibration pattern generating unit 22 supplies the calibration data to the halftoning processing unit 16 (in the case of the printer function, the HDD 25 supplies the calibration data to the print unit 17) (S12).

The calibration pattern is outputted by the print unit 17 according to the data supplied from the calibration pattern generating unit 22 (in the case of the printer function, the HDD 25 supplies the calibration data to the print unit 17) (S13). At this point, the collectively selected calibration patterns or the plural simultaneously selected calibration patterns are continuously outputted as the plural calibration patterns by the print unit 17.

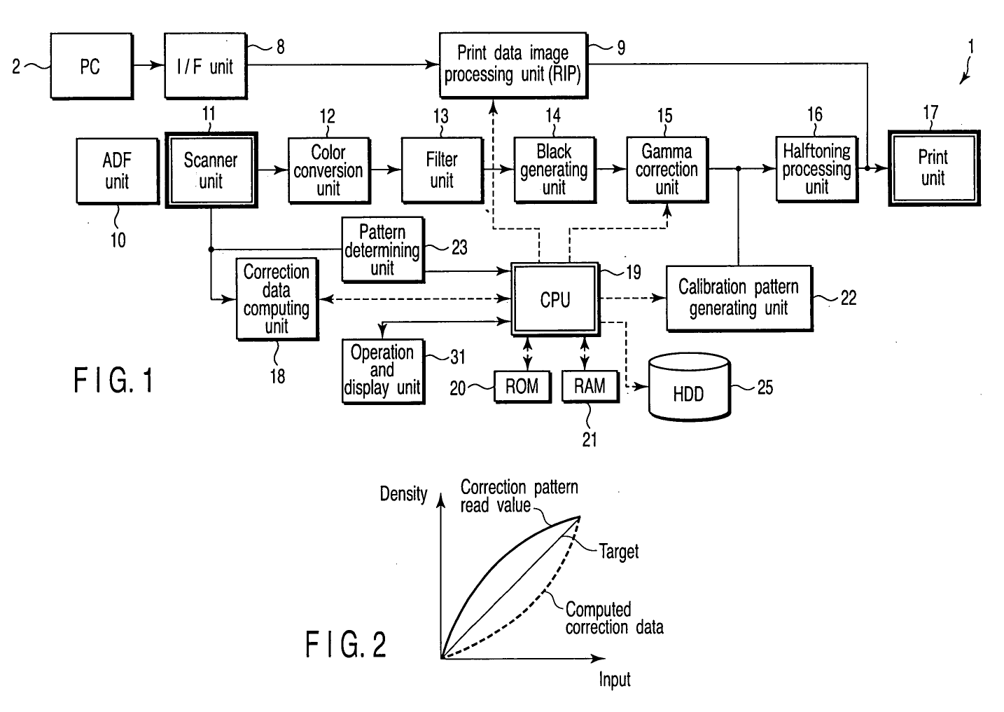

Then, the user sets the printed calibration pattern on the document glass to press a start button of the operation and display unit 31 (S14). The calibration pattern is scanned by the scanner unit 11 (S15), a pattern read value of the image information on the scanned calibration pattern is supplied to the correction data computing unit 18 (S16). As shown in a graph of FIG. 2, a correction curve (correction data) is computed based on the correction pattern read value and the target value, the correction curve is supplied to a control unit in the CPU 19 or the like, and the correction curve is stored in the RAM 21 which is of a storage area in each specified mode (S17). When the next correction is performed, the flow returns to Step S12 again (S18).

In the printer function in the normal image forming operation mode of the image forming apparatus 1, the print data image processing unit 7 appropriately corrects the image information supplied from the PC 2 or the like according to the correction curve stored in the RAM 21, and the print unit 17 forms the image on the recording medium. In the copier function in the normal image forming operation mode of the image forming apparatus 1, the color conversion, the filtering process, the inking and the like are performed to the image information of the document which is placed on and scanned by the scanner unit 11. Then, the image is corrected by the gamma correction using the correction curve stored in the RAM 21 according to the calibration. The corrected image information to which the calibration result is added is supplied to the print unit 17, and the image is formed on the recording medium.

Thus, in the image forming apparatus 1 according to the invention, the calibration patterns corresponding to the plural image forming modes are printed, the correction curves are computed by reading the calibration patterns, and the gamma correction or the RIP process is performed according to the corresponding correction curve. Accordingly, even in the integrated type image forming apparatus, the calibration can easily be performed corresponding to each image forming mode, and the image can easily be formed according to the calibration.

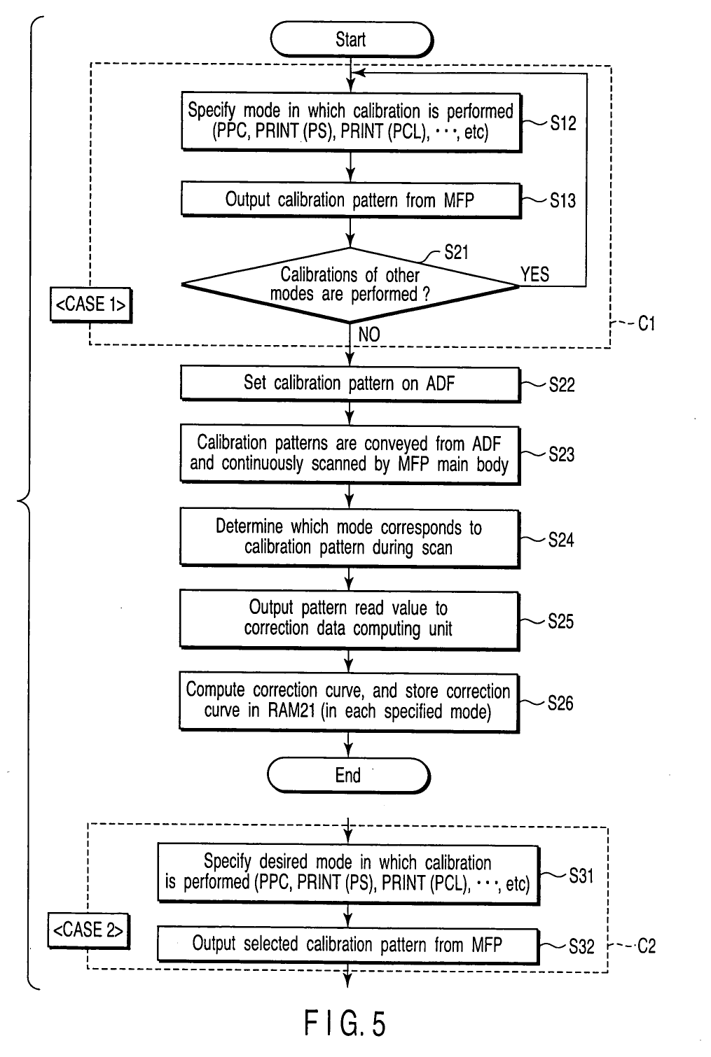

### SECOND EMBODIMENT: FIG. 5

A second embodiment of the invention specifies an image forming apparatus which performs a calibration process by reading plural calibration patterns with the ADF unit. In the image forming apparatus such as an MFP which acts as a copier and a printer, when it cannot be determined which image forming mode corresponds to which correction pattern in reading the plural calibration patterns according to the plural image forming modes, it is necessary that the output and reading of the correction pattern and the correction data computation are integrated into a series of operations, and the series of actions are repeated by the number of calibrations. Even if it is determined which image forming mode corresponds to the correction pattern, it is necessary that the reading operation is performed by the replacing the correction pattern in each time. Because the correction data computing operation is simplified from the reading operation, the case in which the ADF unit is used will be described below.

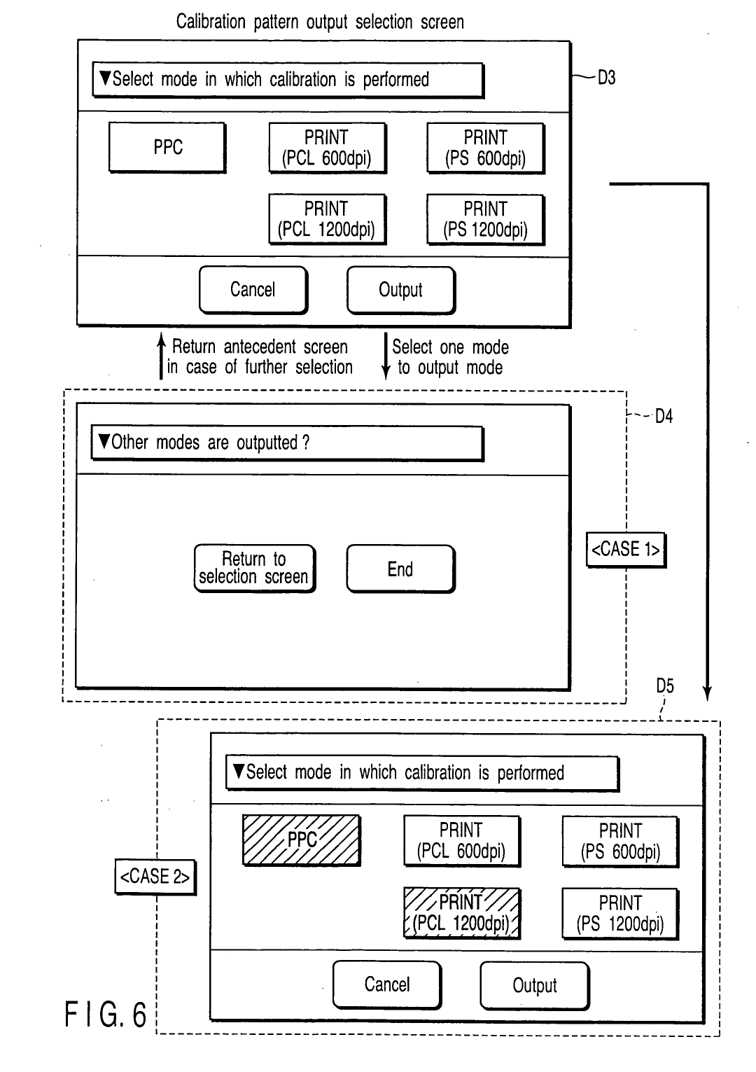

In C1 of Case 1 in the flowchart of FIG. 5, when one image forming mode is selected from a selection screen D3 of FIG. 6 (S21), the calibration pattern generating unit 22 or the HDD 25 output one piece of corresponding calibration data (S13). When another calibration mode is also performed (S21), the flow returns to Step S12, i.e. to the selection screen D3 from a screen D4. Then, in the selection screen D3, one desired image forming mode is selected, and the image of corresponding calibration pattern is formed (S13).

It is also preferable that the plural image forming modes are selected at once. In C2 of Case 2, when the plural image forming modes are selected from an operation screen D5 of FIG. 5 (S31), the calibration pattern generating unit 22 or the HDD 25 supplies the calibration pattern, and the plural calibration patterns are printed (S32). Further, it is also possible that the calibration patterns are collectively printed by using the collective selection screen D1 of FIG. 4 in Step S10 of FIG. 3.

In this case, in the storage area of the CPU 19 and the like, it is preferable that a printout sequence of the plural calibration patterns is stored to utilize a later-mentioned mode determination of the calibration pattern.

Then, the user sets the plural calibration patterns on the ADF unit 10, and presses, for example, the start button of the operation and display unit 31 (S22). The plural calibration patterns are sequentially conveyed from the ADF unit 10, and the scanner unit 11 sequentially reads the calibration patterns by placing the calibration patterns on the document glass (not shown) (S23). Unlike the first embodiment, since the ADF unit 10 is used, it is not necessary that the plural calibration patterns are placed on the document glass again. Therefore, the smooth calibration process can be performed for the plural image forming modes.

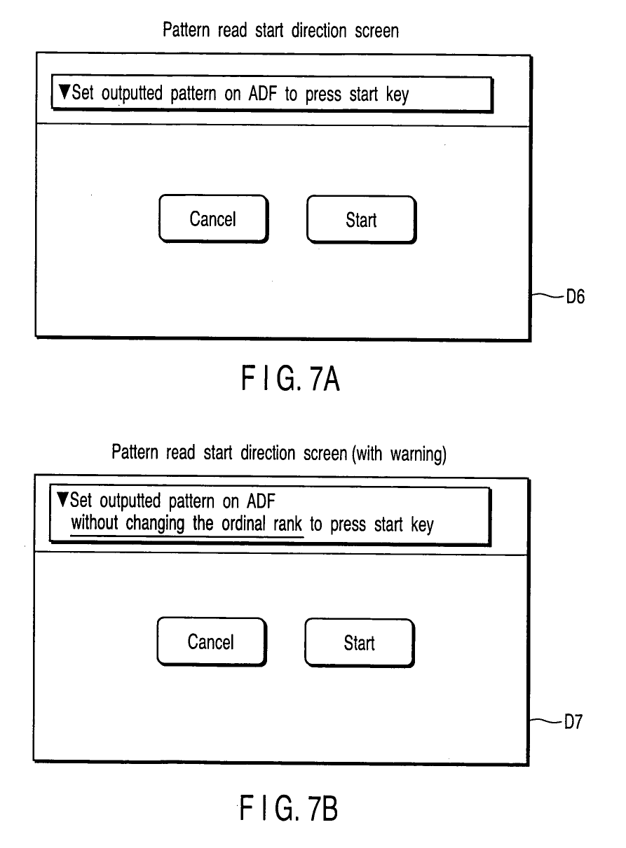

In reading the calibration pattern with the ADF unit 10, as shown in FIG. 7A, it is preferable that a message such as “Set outputted pattern on ADF to press start key” is displayed on the operation and display unit 31 or the like. It is also further preferable to display a warning message such as “Set outputted pattern on ADF without changing sequence, and press start key”. It is preferable that the calibration patterns are securely set on the ADF unit 10 in the order of, for example, “PPC, PRINT (PS 600 dpi), PRINT (PS 1200 dpi), PRINT (PCL 600 dpi), and PRINT (PCL 1200 dpi)”.

As described later referring to FIGS. 10 to 13B, it is possible that the calibration pattern is securely read by the scanner unit 11 by attaching the identification information indicating which image forming mode corresponds to the calibration pattern to the image of the calibration pattern. At this point as well, in the case of the calibration patterns shown in FIGS. 12A and 12B, the user can determine the calibration patterns by the naked eyes.

Then, the calibration patterns are sequentially conveyed to the document glass by using the ADF unit 10, and the calibration patterns are continuously scanned to sequentially output the image information. At this point, which calibration pattern corresponds to which image information is preferably determined by the printout sequence of the plural calibration patterns stored in the storage area of the CPU 19 and the like. Namely, it is determined that the sequence of the plural read calibration patterns are similar to the printout sequence of the printed calibration patterns. Therefore, it is preferable that the following processes are performed according to the determination result.

The read image information (pattern read values) are supplied to the correction data computing unit 18 (S25). The correction curves (correction data) are computed based on the correction pattern read value and the target value shown in the graph of FIG. 2, and the correction curves are stored in the RAM 21 through, for example, the control unit of the CPU 19 in each specified mode (S26). In the operation and display unit 31, it is preferable to show which calibration is ended for the image forming mode.

Thereafter, as with the first embodiment, in the printer function of the image forming apparatus 1, the print data image processing unit 7 appropriately corrects the image information supplied from the PC 2 or the like according to the correction curve stored in the RAM 21, and forms the image on the recording medium. Further, in the copier function, the color conversion, the filtering process, the inking and the like are performed to the image information of the document which is placed on and scanned by the scanner unit 11. Then, the image is corrected by the gamma correction using the correction curve stored in the RAM 21 according to the calibration. The image information to which the calibration result is added for image correction is supplied to the print unit 17, and the image is formed on the recording medium.

Thus, in the second embodiment, the calibration processes can smoothly be performed in the plural modes by using the warning message and the like in the ADF unit 10 and the operation and display unit 31.

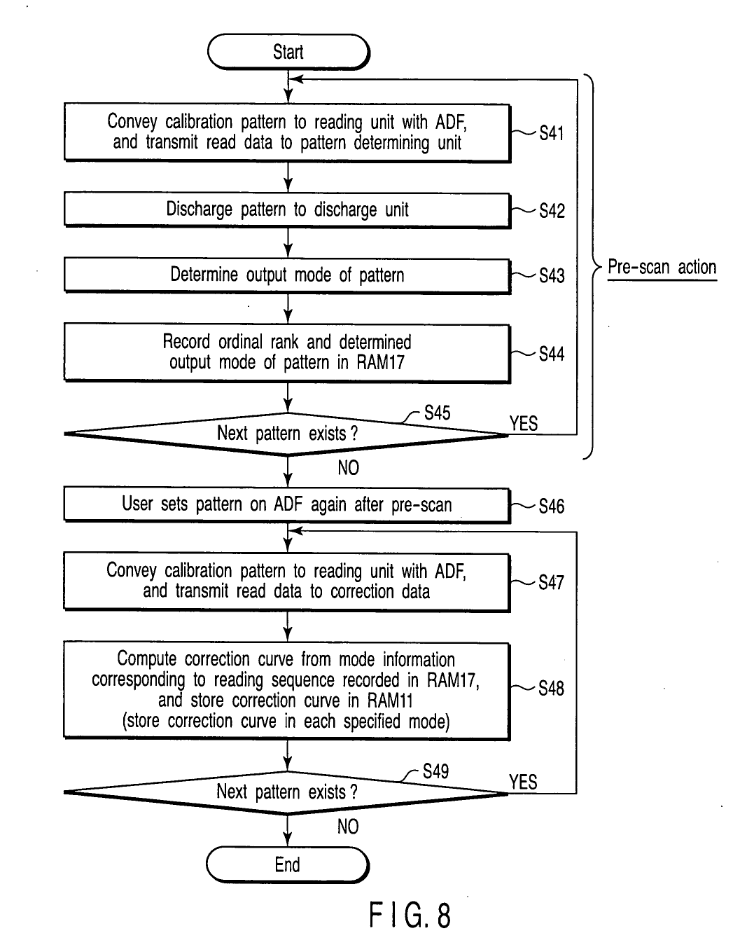

### THIRD EMBODIMENT: FIG. 8

A third embodiment of the invention specifies an image forming apparatus having a function of determining plural calibration patterns. Namely, in the second embodiment, assuming that the sequence of the calibration patterns set on the ADF unit 10 is previously known, the calibration (pattern read and correction data computation) is performed, which allows the process to be efficiently realized for the plural modes. However, when correction data for different patterns are computed such that the sequence is mistakenly changed, there is a possibility that the correction is of the original purpose cannot be reflected, and a density balance and a color balance are lost.

On the contrary, in the image forming apparatus 1 of the third embodiment, the sequence of the calibration patterns is identified and managed by using both the pattern determining unit 23 and the calibration pattern with the identification information shown in FIGS. 10 to 13B.

When the image forming apparatus 1 performs the calibration process, the correction pattern output operation is performed in the same manner as for Steps S10 to S13 in the first embodiment or for Steps S12 to S21 in the second embodiment, and the plural calibration patterns are generated and outputted.

Before the calibration data in each embodiment is supplied to the halftoning processing unit 16 or the print unit 17, the identification information on each image forming mode such as PPC, PRINT (PS 600 dpi), PRINT (PS 1200 dpi), PRINT (PCL 600 dpi), and PRINT (PCL 1200 dpi) is previously added into the calibration data supplied from the calibration pattern generating unit 22 or the HDD 25.

Identification Information

Various modes of the identification information according to the calibration data will be described referring to the drawings.

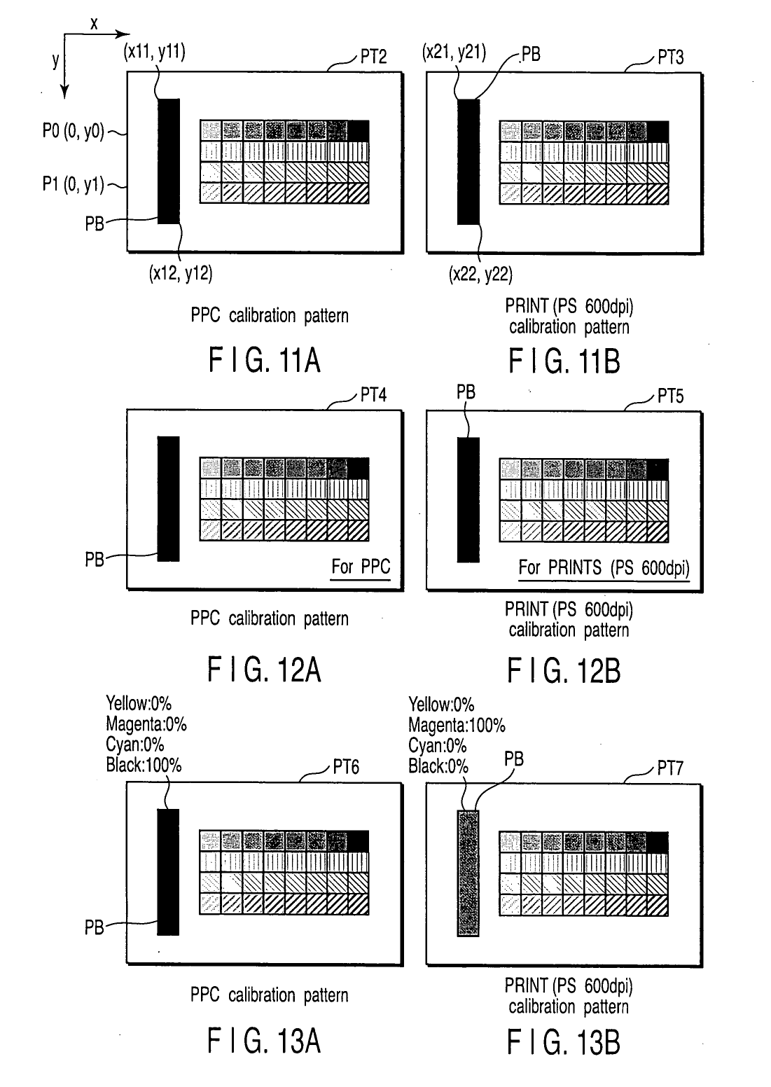

One piece of identification information used in the third embodiment (or fourth embodiment) is a rectangular position-detection bar PB which is provided in a calibration pattern PT1 shown in FIGS. 10 to 11B. The position-detection bar PB specifies which image forming mode corresponds to which calibration pattern. Specifically, in a layout of the calibration pattern PT1 shown in FIG. 10, the calibration pattern PT1 includes gradation patches of each toner color (black, yellow, magenta, and cyan) and the position-detection bar (solid black) PB.

In a layout of a calibration pattern PT2 shown in FIG. 11A, the coordinates of the position-detection bar PB are arranged at (x11, y11) and (x12, y12), and the calibration pattern PT2 is defined as a PPC calibration pattern.

In a layout of a calibration pattern PT3 shown in FIG. 11B, the coordinates of the position-detection bar PB are arranged at (x21, y21) and (x22, y22), and the calibration pattern PT3 is defined as a “PS 600 dpi” calibration pattern. Namely, the calibration data is previously prepared such that the coordinates of the position-detection bars PB differ from one another according to the type of the image forming mode. That the coordinates are arranged at different positions according to the image forming mode is not always limited to the position-detection bar PB. In any image on the calibration pattern, it is also possible that the coordinates are arranged at different positions.

In layouts of calibration patterns PT3 and PT4 shown in FIGS. 12A and 12B, the calibration data is previously prepared such that the user can identify the calibration pattern which indicates the identification information such as “PPC” identification information and “PS 600 dpi” identification information as the image information. Therefore, even if the user does not have knowledge about the coordinate of the position-detection bar PB, the user can visually understand which image forming mode corresponds to the calibration pattern by the identification information. Accordingly, even if the sequence of the printed calibration patterns is lost, the user can re-arranged the sequence of the plural calibration patterns in a desired sequence to cause the ADF unit 10 to read the calibration patterns.

In layouts of calibration patterns PT6 and PT7 shown in FIGS. 13A and 13B, the same layouts are formed while being independent of the image forming mode, and the calibration patterns PT6 and PT7 differ from each other in the density of the position-detection bar PB or the balance (combination) of the toner amount while corresponding to the image forming mode. Namely, the calibration pattern is used for the “PPC” identification information when black is 100% in the position-detection bar PB, and the calibration pattern is used for the “PS 600 dpi” identification information when magenta is 100% in the position-detection bar PB.

Calibration Process Associated with Pattern Determining Process

The image forming apparatus 1 of the third embodiment in which the pattern determining unit 23 performs the above determining process will be described in detail referring to a flowchart shown in FIG. 8. In the image forming apparatus 1, the calibration pattern is conveyed to the scanner unit 11 by the ADF unit 10, and the data read by the scanner unit 11 is sent to the pattern determining unit 23 (S41). The calibration pattern is discharged to a discharge unit (not shown) by the ADF unit 10 (S42). The pattern determining unit 23 determines the type of the calibration pattern in a later-mentioned way (S43) An ordinal rank and the determined image forming mode of the calibration pattern are recorded in the RAM 21 (S44). The processes from Step S41 to Step S44 are performed to all the calibration patterns (S45).

When the image forming modes of all the calibration patterns are found, the plural calibration patterns located on the discharge unit are reset on the ADF unit 10 (S46). The calibration patterns are conveyed to the scanner unit 11, and the image data read by the scanner unit 11 is supplied to the correction data computing unit 18 (S47). The correction curve is computed by the mode information corresponding to the read ordinal rank recorded in the RAM 21, and the correction curve is stored in the RAM 21 (S48). When the process in Step S48 is performed for all the calibration patterns, the calibration process is completed (S49). Then, as with the first and second embodiments, the image forming processes such as the gamma correction and the print data image processing according to the amount of correction by the calibration process are performed in the normal image forming operation mode.

Pattern Determining Process

(Pattern Determination by Coordinate)

The pattern determining process in Step S43 will be described, particularly the determining process by the coordinate of the position-detection bar PB and the determining process by the density of the position-detection bar PB with respect to the calibration patterns shown in FIGS. 11A and 11B will be described.

It is assumed that, as shown in FIG. 10, the layout of the calibration pattern includes the gradation patches of each toner color (black, yellow, magenta, and cyan) and the position-detection bar (solid black) PB. As shown in FIGS. 11A and 11B, when the arrangements can be changed according to the image forming modes to detect the coordinates, each image forming mode can be determined. It is assumed that a proceeding direction of the scanner unit 11 (line scan) with respect to the calibration pattern is set at an x-direction of FIG. 11. Two points P0 and P1 shown in FIG. 11A indicate a measurement start position for computing the coordinates of the position-detection bars. At the two points, front-end coordinates of the position-detection bar are determined in each one line data transmitted from the scanner unit 11 in the following manner. Assuming that y11<y0, and y1<y12,
(x, y0): if (R0<THR && G0<THG && B0<THB) then P0x=cx0
   else cx0++
(x, y1): if (R1<THR && G1<THG && B1<THB) then P1x=cx1
   else cx1++,
      where (R0, G0, G0) is an RGB read value of one line data in the y0 coordinate of P0, (R1, G1, B1) is the RGB read value of one line data in the y1 coordinate of P1, THR, THG, and TBB are thresholds for detecting the position-detection bar, and cx0 and cx1 are counters for determining the x-coordinates P0x and P1x of the front-end positions in the x-direction of the position-detection bar. Further, the start positions P0y and P1y in a line direction (y-direction) are determined in the same manner at the time when both P0x and P1x are confirmed. Assuming that the x-coordinate is set at Px when both P0x and P1x are confirmed,
if (Rx0<THR && Gx0<THG && Bx0<THB) then P0y=cy0
   else cy0++
if (Rx1<THR && Gx1<THG && Bx1<THB) then P1y=cy1
   else cy1++
      In the above expressions, the start coordinate of (Rx0, Gx0, Bx0) is set at (Px, 0), and the start coordinate of (Rx1, Gx1, Bx1) is set at (Px+w, 0). At this point the expressions satisfy 0<w<x12−x11.

It is determined that the position-detection bar can be identified by confirming the four-point coordinates. However, when P0x and P1x differ largely from each other, or when Py0 and Py1 differ largely from each other, there is a high possibility that the calibration pattern is conveyed while largely deformed or the calibration pattern is not the prepared calibration pattern. Therefore, it is determined that the position-detection bar cannot be identified, and the determination is corrected. In the case where not only the coordinate closest to the detected coordinate exists in the set of the coordinates of each image forming mode stored in the ROM 20, but also a distance between the detected coordinate and the coordinate closest to the detected coordinate exists within a predetermined range, it can be determined that the detected coordinate is used for the image forming mode. When the image forming mode cannot be identified, an error message is displayed on the operation and display unit 31.

(Pattern Determination by Density)

On the contrary, the image forming mode is not determined by detecting the coordinate information, but the same layouts are formed in any image forming mode, and the density of the position-detection bar or the color balance of the toner amount constituting the position-detection bar is given in each image forming mode as shown in FIG. 12. Therefore, the image forming mode can also be determined. With reference to the procedure, in determining the position-detection bar in the above manner, THRs, THGs, and THBs corresponding to the number of modes are prepared respectively, and the determination result is obtained by the confirmation of the combination of THR, THG, and THB. Determination accuracy is improved by verifying correctness for the computed coordinate values.
if (Rx0<THR && Gx0<THG && Bx0<THB) then P0y=cy0
   mode0=PPC
else if (Rx0>THR2 && Gx0>THG2 && Bx0<THB2) then P0y=cy0
   mode0=PS600
   similarly for THRs, THGs, and THBs corresponding to the number of modes,
else cy1++
if (Rx1<THR && Gx1<THG && Bx1<THB) then P1y=cy1
   mode1=PPC
else if (Rx1>THR2 && Gx1>THG2 && Bx1<THB2) then P1y=cy1
   mode1=PS600
   . . . , similarly for THRs, THGs, and THBs corresponding to the number of modes, else cy1++.

Where mode0 and mode1 indicate the image forming mode determined based on the RGB value when the front-end coordinate can be detected for P0 and P1.

Similarly the values are also computed with respect to the y-direction.

That the modes detected as mode0x=mode1x=mode0y=mode1y correspond to one another is preferably added to the conditions of the image forming mode determination.

Pattern Determining Process

(Pattern Determination by Density)

The pattern determining process in Step S43 will be described, particularly the determining process by the coordinate of the position-detection bar PB and the determining process by the density of the position-detection bar PB with respect to the calibration patterns shown in FIGS. 13A and 13B will be described. Namely, the image forming mode is not determined by detecting the coordinate information, but the same layouts are formed in any image forming mode, and the density of the position-detection bar PB or the color balance of the toner amount constituting position-detection bar PB is given in each image forming mode as shown in FIGS. 13A and 13B. Therefore, the image forming mode can also be determined.

With reference to the procedure, in determining the position-detection bar in the above manner, THRs, THGs, and THBs corresponding to the number of modes are prepared respectively, and the determination result is obtained by the confirmation of the combination of THR, THG, and THB. The determination accuracy is improved by verifying correctness for the computed coordinate values.
if (Rx0<THR && Gx0<THG && Bx0<THB) then P0y=cy0
   mode0=PPC
else if (Rx0>THR2 && Gx0>THG2 && Bx0<THB2) then P0y=cy0
   mode0=PS600
   similarly for THRs, THGs, and THBs corresponding to the number of modes,
else cy1++
if (Rx1<THR && Gx1<THG && Bx1<THB) then P1y=cy1
   mode1=PPC
else if (Rx1>THR2 && Gx1>THG2 && Bx1<THB2) then P1y=cy1
   mode1=PS600
   . . . , similarly for THRs, THGs, and THBs corresponding to the number of modes, else cy1++

Where mode0 and mode1 indicate the image forming mode determined based on the RGB value when the front-end coordinate can be detected for P0 and P1.

Similarly the values are also computed with respect to the y-direction.

That the modes detected as mode0x=mode1x=mode0y=mode1y correspond to one another is preferably added to the conditions of the image forming mode determination.

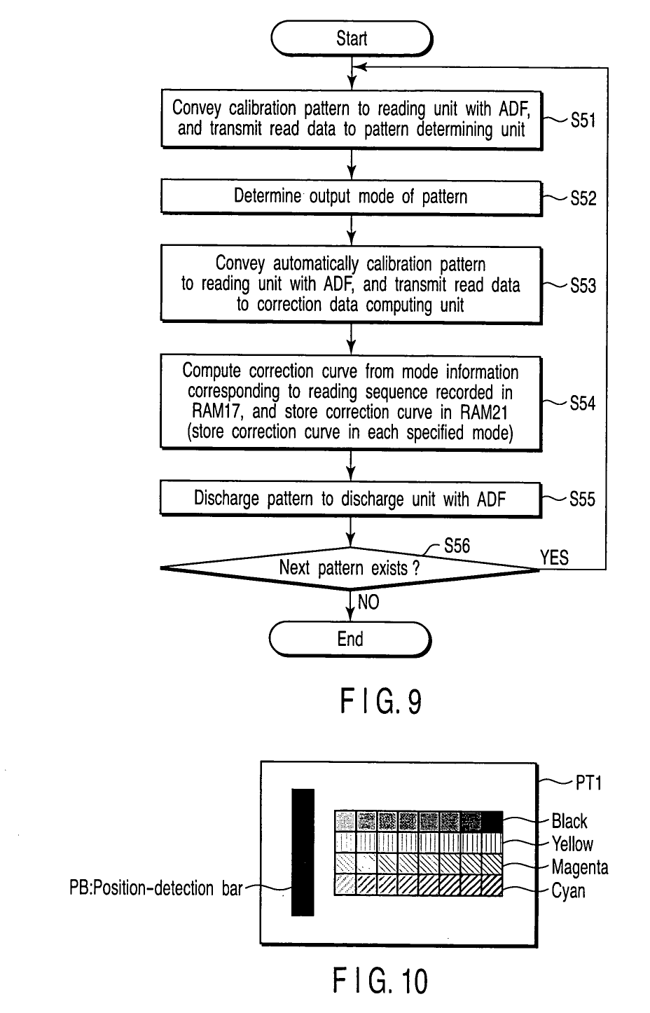

### FOURTH EMBODIMENT: FIG. 9

A fourth embodiment of the invention specifies an image forming apparatus which reads the plural calibration patterns at least twice using the ADF unit. In the image forming apparatus of the third embodiment, due to the structure of the ADF unit, the calibration pattern is conveyed to the scanner unit once to read the calibration pattern, and it is necessary that the calibration pattern read by the scanner unit is discharged to the discharge unit. However, the calibration pattern is not discharged to the discharge unit after the calibration pattern is conveyed to the scanner unit, but the calibration pattern is automatically conveyed to the scanner unit with the ADF unit again, which allows operability to be remarkably improved.

As shown in the flowchart of FIG. 9, in the image forming apparatus 1, the calibration pattern is conveyed to the scanner unit 11 with the ADF unit 10, and the image data read by the scanner unit 11 is supplied to the pattern determining unit 23 (S51). The pattern determining unit 23 determines the image forming mode of the calibration pattern by the above-described manner and the like (S52). Then, the ADF unit 10 automatically conveys the calibration pattern to the scanner unit 11 again, and the data read by the scanner unit 11 is transmitted to the correction data computing unit 18 (S53). Alternatively, in order that the scanner unit 11 performs the second-time reading process after the ADF unit 10 conveys the calibration pattern, the control unit causes the operation and display unit 31 to display a message encouraging the user to press the start button, and waits the press-down of the start button by the user. When the user presses the start button, preferably the calibration pattern is conveyed to the scanner unit 11 again, and the data read by the scanner unit 11 is transmitted to the correction data computing unit 18. Then, the correction data from the correction data computing unit 18 is stored in the RAM 21 in each specified mode (S54). The ADF unit 10 discharges the calibration pattern to the discharge unit (S55). The processes are repeated until the next pattern does not exist (S56).

Other Modifications

In Step S52, when a part of the modes of the plural calibration patterns cannot be identified after the calibration patterns are read once, it is preferable that the operation and display unit 31 displays the message encouraging the user to press the start button in order to return only the calibration pattern which can be identified to the ADF unit 10 to perform the second-time reading process by the scanner unit 11 in Step S53.

Namely, it is preferable that the second-time calibration process is performed by automatically returning only the calibration pattern, in which the corresponding mode can be identified, to the ADF unit 10 to perform the reading process with the scanner unit 11. Therefore, the invalid calibration pattern can be rejected, and the calibration can be performed with high reliability.

Under the control of the control unit 19, when the mode corresponding to a part of the plural calibration patterns cannot be identified after the calibration patterns are read once, it is preferable that the calibration pattern which cannot be identified is discharged by the operation of the AFD unit 10.

Under the control of the control unit 19, when the mode corresponding to the calibration pattern cannot be identified, it is preferable to output the signal for indicating that the mode corresponding to the calibration pattern cannot be identified, or it is preferable that the operation and display unit 31 displays the message that the mode corresponding to the calibration pattern cannot be identified.

When the process of calibrating the modes corresponding to the plural calibration patterns read by the scanner unit 11 is completed under the control of the control unit 19, it is preferable to output the signal for indicating the completion of the calibration process at each time, or it is preferable that the operation and display unit 31 displays the message of the completion of the calibration process at each time.

When all the processes of calibrating the modes corresponding to the plural calibration patterns are completed under the control of the control unit 19, it is preferable to output the signal for indicating a list of all the completed modes and the completion of the calibration process for all the modes, or it is preferable that the operation and display unit 31 displays the list of all the completed modes and the completion of the calibration process for all the modes.

Thus, in image forming apparatus of the fourth embodiment, the plural calibration patterns are read at least twice using the ADF unit. Therefore, the calibration process can be performed for the plural image forming modes with no user's operation.

As described above, those skilled in the art can realize the invention by the various embodiments. However, it is further understood by those skilled in the art that various changes and modifications may be easily made in the invention without departing from the spirit and scope thereof and that the invention may be applied to various changes and modifications without any inventive ability. Accordingly, the invention covers the broad scope consistent with the disclosed principle and novel features, and the invention is not limited to the above-described embodiments.

What is claimed is:

1. An image forming apparatus comprising:
a recording unit which records a plurality of calibration data;
an image forming unit which reads said plurality of calibration data from the recording unit, and forms images of a plurality of calibration patterns on a recording medium according to said plurality of calibration data;
a reading unit which reads the formed images of said plurality of calibration patterns to output image data;
a computing unit which receives a plurality of image data according to the plurality of calibration patterns read by the reading unit, and computes a plurality of image correction amounts by comparing the plurality of image data to a plurality of reference image data previously prepared;
an image processing unit which performs image correction to document image data newly read by the reading unit, according to the plurality of image correction amounts computed by the computing unit; and
a control unit which controls each unit so as to cause the image forming unit to form said plurality of calibration patterns in a calibration operation mode; to cause the reading unit to read said plurality of calibration patterns; to cause the computing unit to compute said plurality of image correction amounts based on the image data of the read calibration pattern to store said plurality of image correction amounts in a storage area; to cause the image processing unit to perform a correction process of the document image data newly read by the reading unit in a normal image forming operation mode based on the image correction amount; and to cause the image forming unit to form an image on the recording medium according to the image data to which the correction process has been performed.

2. An image forming apparatus according to claim 1, wherein the control unit performs the control such that, when the control unit receives a selection signal for a desired mode of a plurality of modes which correspond to said plurality of calibration data in the recording unit in a one-by-one manner, the calibration data corresponding to the selected mode is read from the recording unit to perform the subsequent calibration process.

3. An image forming apparatus according to claim 1, wherein the control unit performs the control such that, when the control unit receives a selection signal for collectively selecting all of a plurality of modes which correspond to said plurality of calibration data in the recording unit in a one-by-one manner, all the calibration data are read from the recording unit and the image forming unit forms the calibration patterns corresponding to all the calibration data on the recording medium to continuously output the calibration patterns.

4. An image forming apparatus according to claim 1, wherein the control unit performs the control such that a display unit displays a plurality of modes corresponding to said plurality of calibration data in the recording unit in ma one-by-one manner, all the calibration data are read from the recording unit when the control unit receives a selection signal for collectively selecting all the modes from an operation unit, and the image forming unit forms the calibration patterns corresponding to all the calibration data on the recording medium to continuously output the calibration patterns.

5. An image forming apparatus according to claim 1, wherein the control unit performs the control such that a display unit displays a screen in which a plurality of modes corresponding to said plurality of calibration data in the recording unit are collectively selected in a one-by-one manner and the display unit displays a selection screen of said plurality of modes when the collective selection is not received from the operation unit.

6. An image forming apparatus according to claim 1, further comprising an auto document feeder (ADF) which automatically conveys a plurality of documents to the reading unit.

7. An image forming apparatus according to claim 1, wherein the control unit stores an output sequence of the images of said plurality of calibration patterns formed by the image forming unit in the storage area, and determines which calibration pattern corresponds to the read image information based on the output sequence when the reading unit reads the image of the calibration pattern.

8. An image forming apparatus according to claim 1, wherein the control unit causes the display unit to, when the reading unit reads recording media having formed therein the images of said plurality of calibration patterns, display a message encouraging a user in order to read the recording media of said plurality of calibration patterns in the order in which the image forming unit outputs the calibration patterns.

9. An image forming apparatus according to claim 1, wherein the image forming unit forms an image on the recording medium while identification information for identifying which mode corresponds to the calibration pattern is attached to the calibration pattern.

10. An image forming apparatus according to claim 1, wherein the control unit stores the output sequence of the images of said plurality of calibration patterns formed by the image forming unit in the storage area, and causes the display unit to display a message encouraging the user to set the corresponding calibration patterns on the reading unit according to the output sequence.

11. An image forming apparatus according to claim 1, wherein the control unit detects which mode corresponds to which calibration pattern based on the image data of said plurality of calibration patterns read by the reading unit, and performs the following calibration processes according to the detection result.

12. An image forming apparatus according to claim 11, wherein the control unit detects which mode corresponds to which calibration pattern based on the identification information on the calibration pattern.

13. An image forming apparatus according to claim 1, wherein the image forming unit forms images according to the modes corresponding to the calibration patterns while positions of the calibration patterns differ from one another on the recording media, and the control unit detects which mode corresponds to which calibration pattern according to the positions of said plurality of calibration patterns on the recording media, and performs the following calibration processes according to the detection result.

14. An image forming apparatus according to claim 1, wherein the image forming unit forms images according to the modes corresponding to the calibration patterns while positions of rectangular patterns in the calibration patterns differ from one another on the recording media, and
the control unit detects which mode corresponds to which calibration pattern according to the positions of the rectangular patterns in the calibration patterns on the recording media, and performs the following calibration processes according to the detection result.

15. An image forming apparatus according to claim 1, wherein the image forming unit forms images according to the modes corresponding to the calibration patterns while toner amounts and toner combinations of the rectangular patterns in the calibration patterns differ from one another, and
the control unit detects which mode corresponds to which calibration pattern according to the toner amounts and the toner combinations of the rectangular patterns in said plurality of calibration patterns read by the reading unit, and performs the following calibration processes according to the detection result.

16. An image forming apparatus according to claim 2, wherein, after the reading unit reads said plurality of calibration patterns to identify the modes corresponding to said plurality of calibration patterns, the control unit returns said plurality of calibration patterns to the ADF again and causes the display unit to display a message encouraging the user to press a start switch such that the reading unit performs the second-time reading process.

17. An image forming apparatus according to claim 2, wherein, when the reading unit reads said plurality of calibration patterns once and a mode of a part of said plurality of calibration patterns cannot be identified, the control unit returns said plurality of calibration patterns to the ADF and causes the display unit to display a message encouraging the user to press a start switch such that the reading unit performs the second-time reading process.

18. An image forming apparatus according to claim 2, wherein the control unit performs the second-time calibration process by automatically returning only the calibration pattern in which the corresponding mode can be identified to the ADF to read the calibration pattern with the reading unit.

19. An image forming apparatus according to claim 18, wherein, when the reading unit reads said plurality of calibration patterns once and a mode corresponding to a part of the calibration patterns cannot be identified, the control unit discharges the calibration pattern which cannot be identified.

20. An image forming method comprising;
reading a plurality of calibration data from a storage area to form images of a plurality of calibration patterns on a recording medium according to the plurality of calibration data;
reading the formed images of said plurality of calibration patterns to output image data;
receiving a plurality of image data according to said plurality of read calibration patterns, and computing a plurality of image correction amounts by comparing the plurality of image data to a plurality of reference image data previously prepared; and
performing image correction to document image data previously read according to said plurality of computed image correction amounts, and forming the image on the recording medium based on the image data.

21. An image forming apparatus according to claim 18, wherein, when the control unit cannot identify the mode corresponding to the calibration pattern read by the reading unit, the control unit outputs a signal indicating that the mode corresponding to the calibration pattern cannot be identified or causes the display unit to display that the mode corresponding to the calibration pattern cannot be identified.

22. An image forming apparatus according to claim 1, wherein, when the process of calibrating the modes corresponding to said plurality of calibration patterns read by the reading unit is completed, the control unit outputs a signal indicating the fact in each time or causes the display unit to display the fact in each time.

23. An image forming apparatus according to claim 1, wherein, when all the processes of calibrating the modes corresponding to said plurality of calibration patterns read by the reading unit are completed, the control unit outputs a signal indicating a list of completed modes and completion of all the modes or causes the display unit to display the list of completed modes and the completion of all the modes.
